(19) United States
(12) Patent Application Publication
(10) Pub. No.: US 2024/0260297 A1
(43) Pub. Date: Aug. 1, 2024

(54) LOW PROFILE PIXEL HAVING ELECTROLUMINESCENT DEVICES AND SHARED ELECTRODES

(71) Applicants: Chun Chiu Daniel Wong, Palo Alto, CA (US); Ming Huang, Racho Palos Verdes, CA (US)

(72) Inventors: Chun Chiu Daniel Wong, Palo Alto, CA (US); Ming Huang, Racho Palos Verdes, CA (US)

(73) Assignees: Syndiant Inc., Dallas, TX (US); XD Micro (Zhongshan) Optoelectronics Semiconductor Co., Ltd, Zhongshan City, TX (CN)

(21) Appl. No.: 18/104,239

(22) Filed: Jan. 31, 2023

(51) Int. Cl. H10K 50/13; G09G 3/32; G09G 3/3208; H10K 50/115; H10K 50/15; H10K 50/16

(52) U.S. Cl. CPC H10K 50/13; G09G 3/32; G09G 3/3208; G09G 2300/0426; G09G 2300/0804; G09G 2310/08

(57) ABSTRACT

A pixel with multiple electroluminescent devices and shared electrodes is disclosed. In one embodiment of the present invention the pixel includes a top electrode, a bottom electrode, a first shared electrode, a second shared electrode, and three electroluminescent devices. The bottom electrode and the first shared electrode are coupled to and operates the first electroluminescent device. The first shared electrode and the second shared electrode are coupled to and operate the second electroluminescent device. The second shared electrode and the top electrode are coupled to and operate the third electroluminescent device.

### BACKGROUND OF THE INVENTION

### Field of the Invention

The present invention relates to display technology. More specifically, the present invention relates to methods and systems of full color pixels for displays.

### Discussion of Related Art

Modern emissive displays typically include a backplane that contains the image processing circuits and the pixel control circuits. The backplane can also include or be attached to device drivers and light sources, which are driven by the device drivers. Light sources can include, light emitting diodes (LED), micro LED, organic LEDs, fluorescent/plasma devices, quantum dot devices, field emissive devices, and others.

FIG. 1 shows a pixel 100 on a substrate 110 that can be part of a display system. Specifically, FIG. 1 only shows a single pixel of the display, which typically includes millions of pixels. In FIG. 1, a control and driver layer 120 is built on substrate 110. For clarity control and driver layer 120 is drawn as a single layer. However, control and driver layer 120 is typically multiple semiconductor layers and include logic circuits and device drivers to control pixel 100. For clarity these logic circuits and device drivers are omitted in FIG. 1 because the omitted logic circuits and device drivers are well known in the art.

Pixel 100 includes three sub pixels that share a common electrode 170. Each sub pixel includes an electroluminescent device (ELD) and a control electrode. Specifically, the first sub pixel includes a control electrode 134, formed above control and driver layer 120, and an electroluminescent device 140 formed in between control electrode 134 and common electrode 170. The second sub pixel includes a control electrode 135, formed above control and driver layer 120, and an electroluminescent device 150 formed in between control electrode 135 and common electrode 170. The third sub pixel includes a control electrode 136, formed above control and driver layer 120, and an electroluminescent device 160 formed in between control electrode 136 and common electrode 170.

Electroluminescent devices 140, 150, and 160 could be for example, LEDs, organic LEDs, micro LEDs, quantum dot devices. For illustrative purposes in FIG. 1, electroluminescent devices 140, 150, and 160 are organic LEDs, or quantum dot devices. Specifically, electroluminescent device 140 includes a first-type carrier transport layer 145 directly on top of control electrode 134, an electroluminescent layer 143, directly on top of first-type carrier transport layer 145, and a second-type carrier transport layer 141 directly on top of electroluminescent layer 143 and under common electrode 170. If electroluminescent device 140 is an organic LED, electroluminescent layer 143 would include organic LED material such as polymers. If electroluminescent device 150 is a quantum dot device electroluminescent layer 143 would be a quantum dot layer. Electroluminescent device 150 includes a first-type carrier transport layer 155 directly on top of control electrode 135, an electroluminescent layer 153, directly on top of first-type carrier transport layer 155, and a second-type carrier transport layer 151 directly on top of electroluminescent layer 153 and under common electrode 170. Similarly, Electroluminescent device 160 includes a first-type carrier transport layer 165 directly on top of control electrode 136, an electroluminescent layer 163, directly on top of first-type carrier transport layer 165, and a second-type carrier transport layer 161 directly on top of electroluminescent layer 163 and under common electrode 170.

If common electrode 170 is coupled to ground voltage, then electroluminescent devices 140, 150, and 160 can be induced to emit light if control electrodes 134, 136, and 136, respectively, are raised to an appropriate voltage and enough current is allowed to flow through the electroluminescent devices. In such a configuration, first-type carrier transport layers 145, 155, and 165 should be hole transport layers. Conversely, second-type carrier transport layers 141, 151, and 161 should be electron transport layers.

Alternatively, if common electrode 170 is coupled to a high voltage (e.g. Vdd), then electroluminescent devices 140, 150, and 160 can be induced to emit light if control electrodes 134, 136, and 136, respective, are driven to an appropriate lower voltage (e.g. Vss) and enough current is allowed to flow through the electroluminescent devices. In such a configuration, first-type carrier transport layers 145, 155, and 165 should be electron transport layers. Conversely, second-type carrier transport layers 141, 151, and 161 should be hole transport layers.

FIG. 1 is a logic diagram rather than a physical layout of pixel 100. Thus, even though electroluminescent devices 140, 150, and 160 appear in a row in FIG. 1, in an actual display they could have different physical layouts depending on the specific way the sub-pixels are being used. For example, in some displays the sub-pixels of pixel 100, are arranged in a roughly square shape. Common Electrode 170 could be controlled from above, or by device and driver layer 120 using vias or other connectors (not shown) that are made using well known and conventional methods.

The transition from standard definition video to high definition video and beyond has created a great demand for higher resolution displays. However, for many displays, in particular for micro displays, the size of the pixel is becoming a limiting factor for the density of pixels in a display. One conventional method to reduce the size of a pixel is to stack the sub pixels vertically as shown in FIG. 2.

FIG. 2 shows a stacked pixel 200 on a substrate 210 that can be used in a display. Specifically, FIG. 2 only shows a single pixel of the display, which typically includes millions of pixels. In FIG. 2, a control and driver layer 220 is built on substrate 210. For clarity control and driver layer 220 is drawn as a single layer. However, control and driver layer 220 is typically multiple semiconductor layers and include logic circuits and device drivers to control pixel 200.

Pixel 200 includes three sub pixels that share a common electrode 270. Common electrode 270 includes three horizontal layers that are individually labeled 270A, 270B, and 270C in FIG. 2; and a vertical portion that connects the three horizontal layers. Each sub pixel of pixel 200 includes an electroluminescent device (ELD) and a control electrode. Specifically, the first sub pixel includes a control electrode 234, formed above control and driver layer 220, and an electroluminescent device 240 formed in between control electrode 234 and common electrode layer 270A. An insulating layer 274 is formed over common electrode layer 270A to prevent shorting multiple sub pixels to each other. The second sub pixel includes a control electrode 235, formed on insulating layer 274, and an electroluminescent device 250 formed in between control electrode 235 and common electrode layer 270B. A second insulating layer 272 is formed on common electrode layer 270B. The third sub pixel includes a control electrode 236, formed on insulating layer 272, and an electroluminescent device 260 formed in between control electrode 236 and common electrode layer 270C.

Pixel 200 also includes insulating regions 282, 284, and 286. Insulating region 282 separates electroluminescent devices 260 and common electrode 237 from the vertical portion of common electrode 270. Control electrodes 234, 235, and 236 as well as common electrode 270 can be connected to control and driver layer 220 using vias or other connectors (not shown) that are made using well known and conventional methods.

As in FIG. 1, electroluminescent devices 240, 250, and 260 in FIG. 2 are illustrated as organic LEDs, or quantum dot devices. Specifically, electroluminescent device 240 includes a first-type carrier transport layer 245 directly on top of control electrode 234, an electroluminescent layer 243, directly on top of first-type carrier transport layer 245, and a second-type carrier transport layer 241 directly on top of electroluminescent layer 243 and under common electrode layer 270A. Electroluminescent device 250 includes a first-type carrier transport layer 255 directly on top of control electrode 235, an electroluminescent layer 253, directly on top of first-type carrier transport layer 255, and a second-type carrier transport layer 251 directly on top of electroluminescent layer 253 and under common electrode layer 270B. Similarly, Electroluminescent device 260 includes a first-type carrier transport layer 265 directly on top of control electrode 236, an electroluminescent layer 263, directly on top of first-type carrier transport layer 265, and a second-type carrier transport layer 261 directly on top of electroluminescent layer 263 and under common electrode layer 270C. Electroluminescent devices 240, 250, and 260 operate in the same manner as described above with regards to electroluminescent devices 140, 150, and 160 except that the devices are stacked vertically.

While stacked sub-pixels allow higher density due to having smaller foot print than non-stacked pixels, the stacked sub-pixels are more difficult and more costly to manufacture. The primary problem is the number of processing layers required to make the pixel with stacked sub-pixels. Hence there is a need for a method or system create pixels that have small foot prints but are easier to and to manufacture than conventional pixels.

### SUMMARY

Accordingly, the present invention provides a novel pixel design having stacked sub-pixels that require fewer layers than conventional pixels. Reducing the layer of the pixel reduces the cost and the complexity of manufacturing the novel pixel. In accordance with one embodiment of the present invention, a pixel includes a bottom electrode coupled to a first electroluminescent device. A first shared electrode is also coupled to the first luminescent device. The bottom electrode and the first shared electrode operates the first electroluminescent device. A second electroluminescent device is coupled to the first shared electrode and to a second shared electrode. The first shared electrode and the second shared electrode operate the second electroluminescent device. A third electroluminescent device is coupled to the second shared electrode and a top electrode. The second shared electrode and the top electrode operate the third electroluminescent device.

The pixel can be built as a stacked pixel to conserve space on a display. Specifically, the first electroluminescent device is stacked on top of the bottom electrode and the first shared electrode is stacked on top the first electroluminescent device. The second electroluminescent device is stacked on top of the first shared electrode and the second shared electrode is stacked on top of the second electroluminescent device. The third electro luminescent device is stacked on top of the second shared electrode and the top electrode is stacked on top of the third electroluminescent device.

The present invention will be more fully understood in view of the following description and drawings.

### BRIEF DESCRIPTION OF THE DRAWINGS

FIG. 1 illustrates a conventional pixel.

FIG. 2 illustrates a conventional pixel having stacked sub-pixels.

FIGS. 3A-3C illustrates the formation of a pixel in accordance with one embodiment of the present invention.

FIG. 4 illustrates the operation of a pixel in accordance with one embodiment of the present invention.

FIG. 5 is timing diagram illustrating the operation of a pixel in accordance with one embodiment of the present invention.

FIG. 6 illustrates the operation of a pixel in accordance with one embodiment of the present invention.

FIG. 7 is timing diagram illustrating the operation of a pixel in accordance with one embodiment of the present invention.

### DETAILED DESCRIPTION

As explained above, smaller pixel designs are needed the as the resolution of displays increase. Pixels in accordance with the present invention are easier and cheaper to manufacture than conventional pixels.

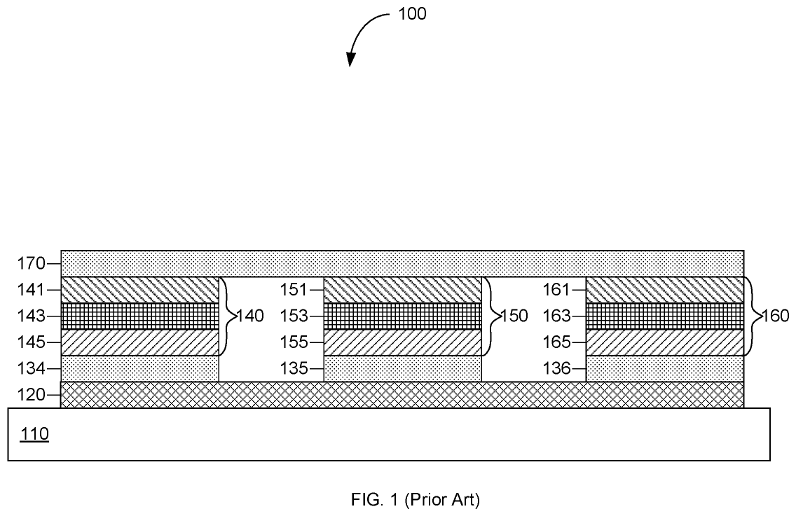

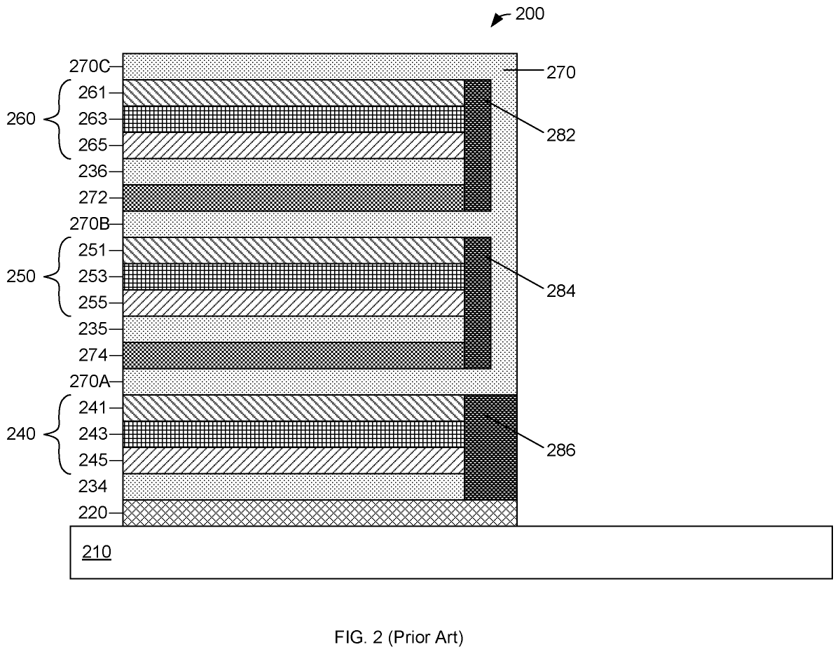

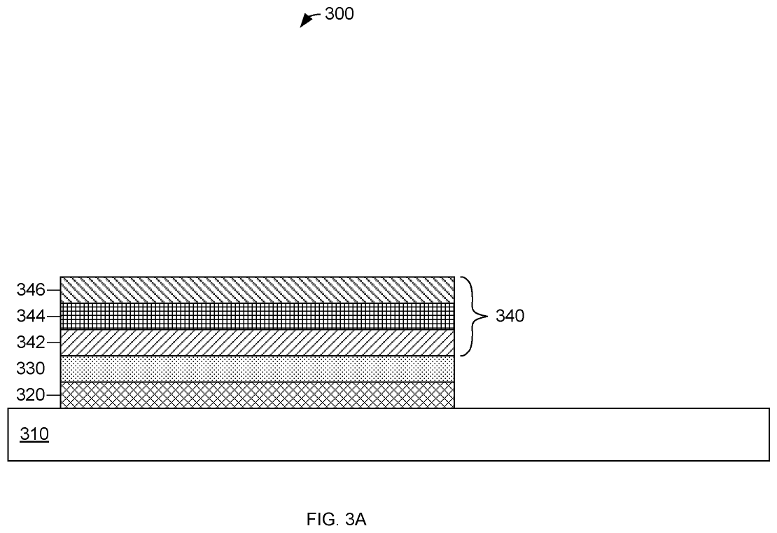

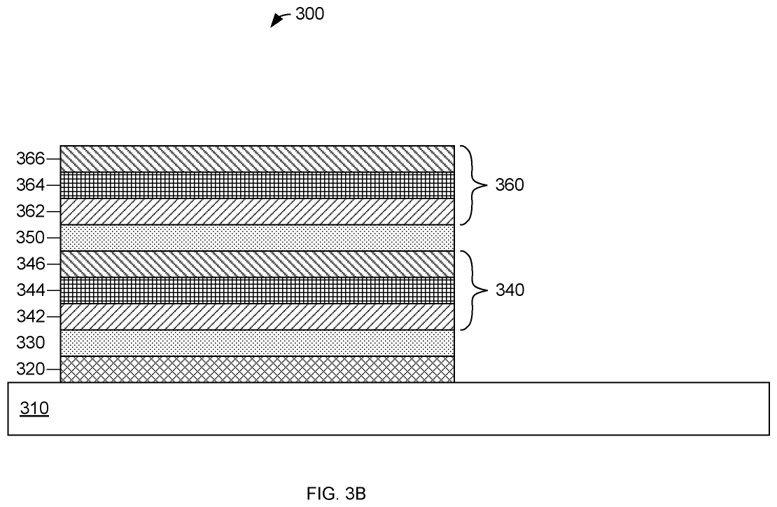

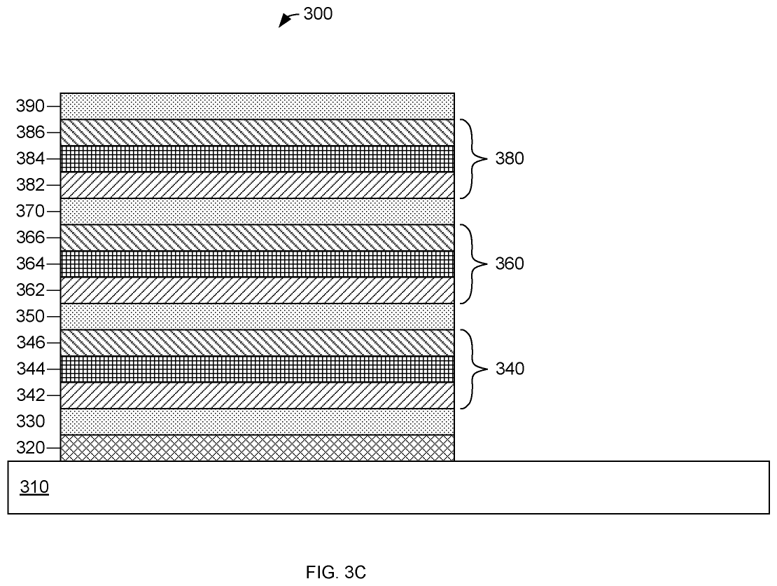

FIGS. 3A-3C illustrate the formation of a pixel 300 in accordance with one embodiment of the present invention. As shown in FIG. 3A, a control and driver layer 320 is built on a substrate 310. For clarity control and driver layer 320 is drawn as a single layer. However, control and driver layer 320 is typically multiple semiconductor layers and include logic circuits and device drivers to control pixel 300. A bottom electrode 330 is formed above control and driver layer 320. Then, an electroluminescent device 340 is formed directly on bottom electrode 330. As in FIGS. 1 and 2, electroluminescent device 340 in FIG. 3 is illustrated as an organic LED or quantum dot devices. Accordingly, electroluminescent device 340 includes a first-type carrier transport layer 342 directly on top of bottom electrode 330, an electroluminescent layer 344, directly on top of first-type carrier transport layer 342, and a second-type carrier transport layer 346 directly on top of electroluminescent layer 344. However other types of electroluminescent devices are used in other embodiments of the present invention. In many embodiments of the present invention, bottom electrode 330 is made of a reflective conducting material, such as aluminum, copper, or silver. Making bottom conductor 330 reflective can improve the brightness of pixel 300.

As shown in FIG. 3B, a shared electrode 350 is formed directly on top of electroluminescent device 340. Then, electroluminescent device 360 is formed directly on shared electrode 350. As will be explained in more detail below, shared electrode 350 can be used to operate both electroluminescent device 340 and electroluminescent device 360. Electroluminescent device 350 includes a first-type carrier transport layer 362 directly on top of bottom electrode 330, an electroluminescent layer 364, directly on top of first-type carrier transport layer 362, and a second-type carrier transport layer 366 directly on top of electroluminescent layer 364. However other types of electroluminescent devices are used in other embodiments of the present invention. Shared electrode 350 should be made of a transparent conducting material such as Indium Tin Oxide (ITO), Indium Zinc Oxide (IZO), or similar materials. Similarly, electroluminescent device 360 should be made with transparent materials so that light from electroluminescent device 340 can reach the top of pixel 300.

As shown in FIG. 3C, a shared electrode 370 is formed directly on top of electroluminescent device 360. Then, an electroluminescent device 380 is formed directly on shared electrode 370. As will be explained in more detail below, shared electrode 370 can be used to operate both electroluminescent device 360 and electroluminescent device 380. Then, a top electrode 390 is formed on top of electroluminescent device 380. Electroluminescent device 380 includes a first-type carrier transport layer 382 directly on top of bottom electrode 370, an electroluminescent layer 384, directly on top of first-type carrier transport layer 382, and a second-type carrier transport layer 386 directly on top of electroluminescent layer 384. However other types of electroluminescent devices are used in other embodiments of the present invention.

Shared electrodes 350 and 370, top electrode 390, and bottom electrode 330 can be connected to control and driver layer 220 using vias or other connectors (not shown) that are made using well known and conventional methods.

Like pixel 200, pixel 300 includes three sub pixels. However pixel 300 use two shared electrodes 350 and 370, a top electrode 380 and a bottom electrode 330 instead of a three layered common electrode and three control electrodes line as used in pixel 200. Thus, pixel 300 uses two fewer electrode layers than pixel 200. Furthermore, because shared electrodes 350 and 370 are used to control multiple electroluminescent devices, insulation layers are not required in pixel 300. Thus pixel 300 has four fewer semiconductor processing layers than pixel 200. Reducing the number of semiconductor processing layers reduces the cost and complexity of manufacturing pixel 300 compared to conventional pixels.

Pixel 300 is typically used in a field sequential color system. In field-sequential color systems, an image frame is divided into three color fields, which are displayed successively at a high speed and relies on the human vision system to fuse the successive fields into a color frame. Typically, for videos a frame time period, is divided into multiple field time periods. Each color field is displayed in one more corresponding field time periods. If the field time periods are small enough a human viewer will only perceive a composite full color frame. In a specific embodiment of the present invention, electroluminescent devices 380, 360, and 340 are tuned to produce blue light, green light, and red light, respectively. Because only one color field is displayed at a time, only one of electroluminescent device 340, 360 or 380 is active at a time. Furthermore, most embodiments of the present invention use pulse width modulation to control the perceived brightness of the electroluminescent devices. Specifically, the percentage of time that each electroluminescent device is turned on during a field time determines the brightness perceived by the viewer.

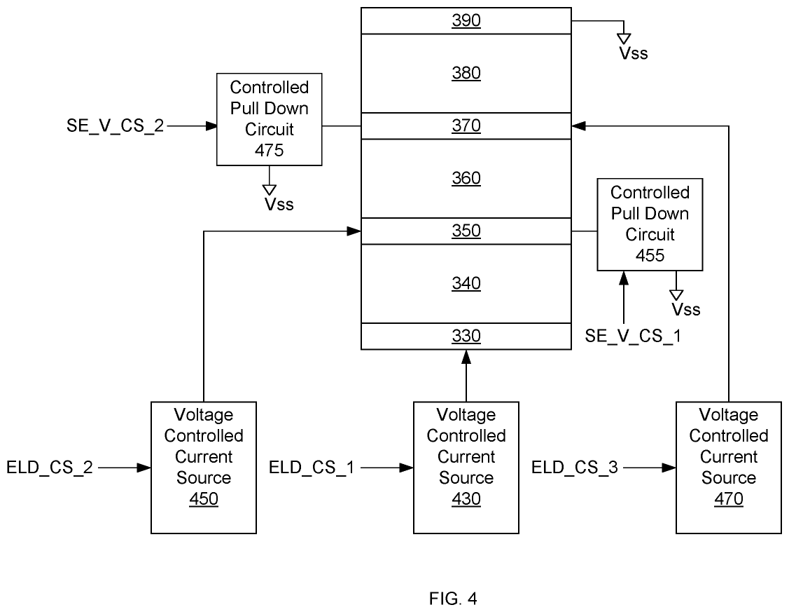

FIG. 4 illustrates the operation of pixel 300 in accordance with one embodiment of the present invention. In FIG. 4, top electrode 390 acts as the anode of pixel 380 and is coupled to ground voltage Vss. Three voltage controlled current sources 430, 450, and 470 are coupled to drive bottom electrode 330, shared electrode 350, and shared electrode 370, respectively. In addition, controlled pull down circuit 475 is coupled between ground voltage Vss and shared electrode 370 and controlled pull down circuit 455 is coupled between ground voltage Vss and shared electrode 350. Controlled pull down circuit 455 is controlled by shared electrode voltage control signal SE_V_CS_1 and controlled pull down circuit 475 is controlled by shared electrode voltage control signal SE_V_CS_2. Controlled pull down circuits 455 and 475 and voltage controlled current sources 430, 450, and 470 would typically be located in control and driver layer 320 (FIG. 3).

Voltage controlled current sources 430, 450, and 470 are controlled by electroluminescent device control signals ELD_CS_1, ELD_CS_2, and ELD_CS_3, which use pulse width modulation activate (i.e. turn on) and deactivate (turn off) electroluminescent devices 340, 360, and 380, respectively (as explained below). When electroluminescent device control signal ELD_CS_1 is at logic high, voltage controlled current source 430 pulls bottom electrode 330 to a high voltage. When electroluminescent device control signal ELD_CS_1 is at logic low, voltage controlled current source 430 is turned off and bottom electrode 330 is not driven by voltage controlled source 430 and be in an high impedance state. The voltage on bottom electrode 330 is said to be floating when in the high impedance state.

Similarly, when electroluminescent device control signal ELD_CS_2 is at logic high, voltage controlled current source 450 pulls shared electrode 350 to a high voltage. When electroluminescent device control signal ELD_CS_2 is at logic low, voltage controlled current source 450 is turned off and shared electrode 350 is not driven by voltage controlled source 450 and be in an high impedance state. The voltage on shared electrode 350 is said to be floating when in the high impedance state. However, shared electrode 350 is also coupled to controlled pull down circuit 455, which can selectively couple shared electrode 350 to ground voltage Vss. Specifically, if shared electrode voltage control signal SE_V_CS_1 is at a first state (e.g. logic low) then controlled pull down circuit 455 is activated to ground shared electrode 350. However if shared electrode voltage control signal SE_V_CS_1 is at a second state (e.g. logic high) then controlled pull down circuit 455 is deactivated and shared electrode 350 would be in the high impedance state or be controlled by voltage controlled current source 450. Generally, controlled pull down circuit 455 is activated to ground shared electrode 350 when electroluminescent device 340 can be activated.

Similarly, when electroluminescent device control signal ELD_CS_3 is at logic high, voltage controlled current source 470 pulls shared electrode 370 to a high voltage. When electroluminescent device control signal ELD_CS_3 is at logic low, voltage controlled current source 470 is turned off and shared electrode 350 is not driven by voltage controlled source 470 and is in the high impedance state. However, shared electrode 370 is also coupled to controlled pull down circuit 475, which can selectively couple shared electrode 370 to ground voltage Vss. Specifically, if shared electrode voltage control signal SE_V_CS_2 is at a first state (e.g. logic low) then controlled pull down circuit 475 is activated to ground shared electrode 370. However if shared electrode voltage control signal SE_V_CS_2 is at a second state (e.g. logic high) then controlled pull down circuit 455 is deactivated and shared electrode 370 would be in the high impedance state or be controlled by voltage controlled current source 470. Generally, controlled pull down circuit 475 is activated to ground shared electrode 370 when electroluminescent device 340 or electroluminescent device 360 can be activated.

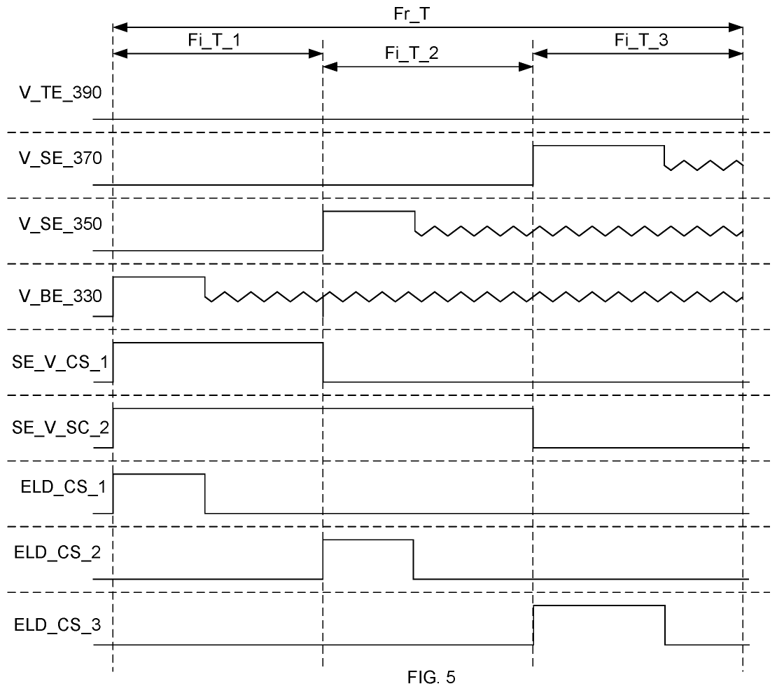

FIG. 5 shows a timing diagram that can be used with pixel 300 in accordance with one embodiment of the present invention. Specifically FIG. 5 shows one frame time period Fr_T, in which one frame of a video is shown on the display. Frame time period Fr_T is divided into three field time periods Fi_T_1, Fi_T_2, and Fi_T_3. As explained above, some embodiments of the present invention use pixel 300 with a field sequential color system. Thus, only one color is displayed in each field time period. In FIG. 5, electroluminescent device 340 is used in field time periods Fi_T_1, electroluminescent device 360 is used in field time periods Fi_T_2, and electroluminescent device 380 is used in field time periods Fi_T_3.

FIG. 5 shows the voltage on top electrode 390, which is labeled V_TE_390, the voltage on shared electrode 370, which is labeled V_SE_370, the voltage on shared electrode 350, which is labeled V_SE_350, and the voltage on bottom electrode 330, which is labeled V_BE_330. In addition, FIG. 5 shows electroluminescent device control signals ELD_CS_1, ELD_CS_2, and ELD_CS_3, which control voltage controlled current sources 430, 450, and 470, respectively. Furthermore, FIG. 5 also shows shared electrode voltage control signals SE_V_CS_1 and SE_V_CS_2, which control controlled pull down circuits 455 and 475, respectively.

As explained above, electroluminescent device control signals ELD_CS_1 controls electroluminescent device 340, which is only active during field time period Fi_T_1. Therefore, during field time periods Fi_T_2 and Fi_T_3, electroluminescent device control signals ELD_CS_1 is at logic low. During field time period Fi_T_1, electroluminescent device control signals ELD_CS_1 is at logic high to turn on electroluminescent device 340 and at logic low to turn off electroluminescent device 340. Thus, in FIG. 5, electroluminescent device control signals ELD_CS_1 is shown to transition to logic high at the beginning of field time period Fi_T_1 and transition to logic low during field time period Fi_T_1 and remain at logic low throughout Field time periods Fi_T_2 and Fi_T_3.

Electroluminescent device control signals ELD_CS_2 controls electroluminescent device 360, which is only active during field time period Fi_T_2. Therefore, during field time periods Fi_T_1 and Fi_T_3, electroluminescent device control signals ELD_CS_2 is at logic low. During field time period Fi_T_2, electroluminescent device control signals ELD_CS_2 is at logic high to turn on electroluminescent device 360 and at logic low to turn off electroluminescent device 360. Thus in FIG. 5, electroluminescent device control signals ELD_CS_2 is shown to transition to logic high at the beginning of field time period Fi_T_2 and transition to logic low during field time period Fi_T_2 and remain at logic low throughout Field time periods Fi_T_1 and Fi_T_3.

Electroluminescent device control signals ELD_CS_3 controls electroluminescent device 380, which is only active during field time period Fi_T_3. Therefore, during field time periods Fi_T_1 and Fi_T_2, electroluminescent device control signals ELD_CS_3 is at logic low. During field time period Fi_T_3, electroluminescent device control signals ELD_CS_3 is at logic high to turn on electroluminescent device 380 and at logic low to turn off electroluminescent device 380. Thus in FIG. 5, electroluminescent device control signals ELD_CS_3 is shown to transition to logic high at the beginning of field time period Fi_T_3 and transition to logic low during field time period Fi_T_3 and remain at logic low throughout Field time periods Fi_T_1 and Fi_T_2.

Shared electrode voltage control signal SE_V_CS_1 controls controlled pull down circuit 455. During field time Fi_T_1, shared electrode voltage control signal SE_V_CS_1 is at logic high which activates controlled pull down circuit 455 to pull the voltage V_SE_350 on shared electrode 350 to a low voltage. During field times Fi_T_2 and FI_T_3, shared electrode voltage control signal SE_V_CS_1 is at logic low to deactivate controlled pull down circuit 455. When deactivated controlled pull down circuit 455 does not control the voltage on shared electrode 350. Thus voltage V_SE_350 on shared electrode 350 would either float or be controlled by voltage controlled current source 450.

Shared electrode voltage control signal SE_V_CS_2 controls controlled pull down circuit 475. During field times Fi_T_1 and Fi_T_2, shared electrode voltage control signal SE_V_CS_2 is at logic high which activates controlled pull down circuit 475 to pull the voltage V_SE_370 on shared electrode 370 to a low voltage. During field time FI_T_3, shared electrode voltage control signal SE_V_CS_2 is at logic low to deactivate controlled pull down circuit 475. When deactivated controlled pull down circuit 475 does not control the voltage on shared electrode 370. Thus voltage V_SE_370 on shared electrode 370 would either float or be controlled by voltage controlled current source 470.

Because top electrode 390 is coupled to ground voltage Vss, voltage V_TE_390 remains at logic low during the entirety of frame time period Fr_T. As explained above, controlled pull down circuit 475 pulls shared electrode 370 to ground voltage Vss when electroluminescent device 340 or electroluminescent device 360 can be activated. Therefore, voltage V_SE_370 on shared electrode 370 is grounded during field time period Fi_T_1 and field time period Fi_T_2. During field time Fi_T_3, voltage V_SE_370 on electrode 370 is controlled by electroluminescent device control signal CLD_CS_3 through voltage controlled current source 470. When electroluminescent device control signal ELD_CS_3 is at logic high, voltage V_SE_370 on shared electrode 370 is pulled to a high voltage and when electroluminescent device control signal ELD_CS_3 is at logic low, voltage V_SE_370 is floating, which is represented by a diagonal line segments in between high and low. While voltage V_SE_370 is floating, shared electrode 370 is not driven and is in a high impedance state.

As explained above, controlled pull down circuit 455 pulls shared electrode 350 to ground voltage Vss when electroluminescent device 340 can be activated. Therefore, voltage V_SE_350 on shared electrode 350 is grounded during field time period Fi_T_1. During field time periods Fi_T_2 and Fi_T_3, voltage V_SE_350 on shared electrode 350 is controlled by electroluminescent device control signal ELD_CS_2 through voltage controlled current source 450. When electroluminescent device control signal ELD_CS_2 is at logic high, voltage V_SE_350 on shared electrode 350 is pulled to a high voltage and when electroluminescent device control signal ELD_CS_2 is at logic low, voltage V_SE_350 is floating. While voltage V_SE_350 is floating, shared electrode 350 is not driven and is in a high impedance state.

During field time periods Fi_T_1, Fi_T_2 and Fi_T_3, voltage V_BE_330 on bottom electrode 330 is controlled by electroluminescent device control signal ELD_CS_1 through voltage controlled current source 430. When electroluminescent device control signal ELD_CS_1 is at logic high, voltage V_BE_330 on bottom electrode 330 is pulled to a high voltage and when electroluminescent device control signal ELD_CS_1 is at logic low, voltage V_BE_330 is floating. While voltage V_BE_330 is floating, bottom electrode 330 is not driven and is in a high impedance state.

An electroluminescent device is active (i.e. emits light) when a voltage difference on the top and bottom of the electroluminescent device causes sufficient current to run through the electroluminescent device. During field time period Fi_T_1, voltage V_TE_390 on top electrode 390, voltage V_SE_370 on shared electrode 370, and voltage V_SE_350 are at ground voltage Vss. Thus, no current flows through electroluminescent device 380 (which is between top electrode 390 and shared electrode 370). Similarly no current flows through electroluminescent device 360 (which is between shared electrode 370 and shared electrode 350). Voltage V_BE_330 on bottom electrode is driven to a high voltage for part of field time period Fi_T_1 and floating during the rest of field time period Fi_T_1. When voltage V_BE_330 is at high voltage electroluminescent device 340 activates because a current flows from bottom electrode 330 (at high voltage) to shared electrode 350 (at ground voltage). But when voltage V_BE_330 is floating no current flows and electroluminescent device 340 is deactivated.

During field time period Fi_T_2, voltage V_TE_390 on top electrode 390 and voltage V_SE_370 on shared electrode 370 are at ground voltage Vss. Thus, no current flows through electroluminescent device 380 (which is between top electrode 390 and shared electrode 370). Voltage V_SE_350 on shared electrode 350 is driven to a high voltage for part of field time period Fi_T_2 and floating during the rest of field time period Fi_T_2. When voltage V_SE_350 is at high voltage electroluminescent device 360 activates because a current flows from shared electrode 350 (at high voltage) to shared electrode 370 (at ground voltage). But when voltage V_SE_350 is floating no current flows and electroluminescent device 360 is deactivated. During field time period Fi_T_2, voltage V_BE_330 on bottom electrode 330 is floating therefore no current flows through electroluminescent device 340, which remains deactivated during field time period Fi_T_2.

During field time period Fi_T_3, voltage V_TE_390 on top electrode 390 is at ground voltage Vss. Voltage V_SE_370 on shared electrode 370 is driven to a high voltage for part of field time period Fi_T_3 and floating during the rest of field time period Fi_T_3. When voltage V_SE_370 is at high voltage electroluminescent device 380 activates because a current flows from shared electrode 370 (at high voltage) to top electrode 390 (at ground voltage). But when voltage V_SE_370 is floating no current flows and electroluminescent device 380 is deactivated. During field time period Fi_T_3, voltage V_BE_330 on bottom electrode 330 and voltage V_SE_350 on shared electrode 350 are floating therefore no current flows through electroluminescent device 340 and electroluminescent device 360, which remain deactivated during field time period Fi_T_3. Thus pixel 300 operating in the manner illustrated by FIG. 4 and FIG. 5 can be used to display full color using a field sequential color system.

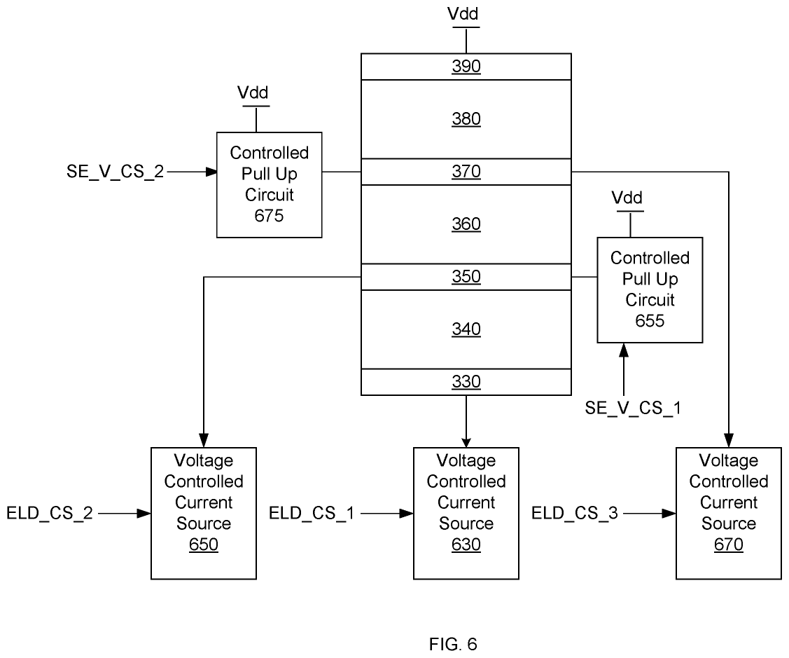

FIG. 6 illustrates the operation of pixel 300 in accordance with another embodiment of the present invention. Three voltage controlled current sources 630, 650, and 670 are coupled to drive bottom electrode 330, shared electrode 350, and shared electrode 370, respectively. In addition controlled pull up circuit 675 is coupled between supply voltage Vdd and shared electrode 370 and controlled pull up circuit 655 is coupled between supply voltage Vdd and shared electrode 350. Controlled pull up circuit 675 is controlled by shared electrode voltage control signal SE_V_CS_1 and controlled pull up circuit 655 is controlled by shared electrode voltage control signal SE_V_CS_2. Controlled pull up circuits 655 and 675 and voltage controlled current sources 630, 650, and 670 would typically be located in control and driver layer 320 (FIG. 3).

Voltage controlled current sources 630, 650, and 670 are controlled by electroluminescent device control signals ELD_CS_1, ELD_CS_2, and ELD_CS3, which use pulse width modulation to turn on and off electroluminescent device 340, 360, and 380, respectively (as explained below). When electroluminescent device control signal ELD_CS_1 is at logic high, voltage controlled current source 630 pulls bottom electrode 330 to a low voltage. (When electroluminescent device control signal ELD_CS_1 is at logic low, voltage controlled current source 630 is turned off and bottom electrode 330 is not driven by voltage controlled source 630 and is in a high impedance state.

Similarly, when electroluminescent device control signal ELD_CS_2 is at logic high, voltage controlled current source 650 pulls shared electrode 350 to a low voltage. When electroluminescent device control signal ELD_CS_2 is at logic low, voltage controlled current source 650 is turned off and shared electrode 350 is not driven by voltage controlled source 650 and is in a high impedance state. However, shared electrode 350 is also coupled to controlled pull up circuit 655, which can selectively couple shared electrode 350 to supply voltage Vdd. Specifically, if shared electrode voltage control signal SE_V_CS_1 is at a first state (e.g. logic low) then controlled pull up circuit 655 is activated to pull up shared electrode 350 to supply voltage Vdd. However if shared electrode voltage control signal SE_V_CS_1 is at a second state (e.g. logic high) then controlled pull up circuit 655 is deactivated and shared electrode 350 would float or be controlled by voltage controlled current source 650. Generally, controlled pull up circuit 655 is activated to pull up shared electrode 350 when electroluminescent device 340 can be activated.

Similarly, when electroluminescent device control signal ELD_CS_3 is at logic high, voltage controlled current source 670 pulls shared electrode 370 to a low voltage. When electroluminescent device control signal ELD_CS_3 is at logic low, voltage controlled current source 670 is turned off and shared electrode 370 is not driven by voltage controlled source 670 and is in a high impedance state. However, shared electrode 370 is also coupled to controlled pull up circuit 675, which can selectively couple shared electrode 370 to supply voltage Vdd. Specifically, if shared electrode voltage control signal SE_V_CS_2 is at a first state (e.g. logic low) then controlled pull up circuit 675 is activated to pull up shared electrode 370 to supply voltage Vdd. However if shared electrode voltage control signal SE_V_CS_2 is at a second state (e.g. logic high) then controlled pull up circuit 655 is deactivated and shared electrode 370 would be in the high impedance state or be controlled by voltage controlled current source 670. Generally, controlled pull up circuit 675 is activated to pull up shared electrode 370 when electroluminescent device 340 or electroluminescent device 360 can be activated.

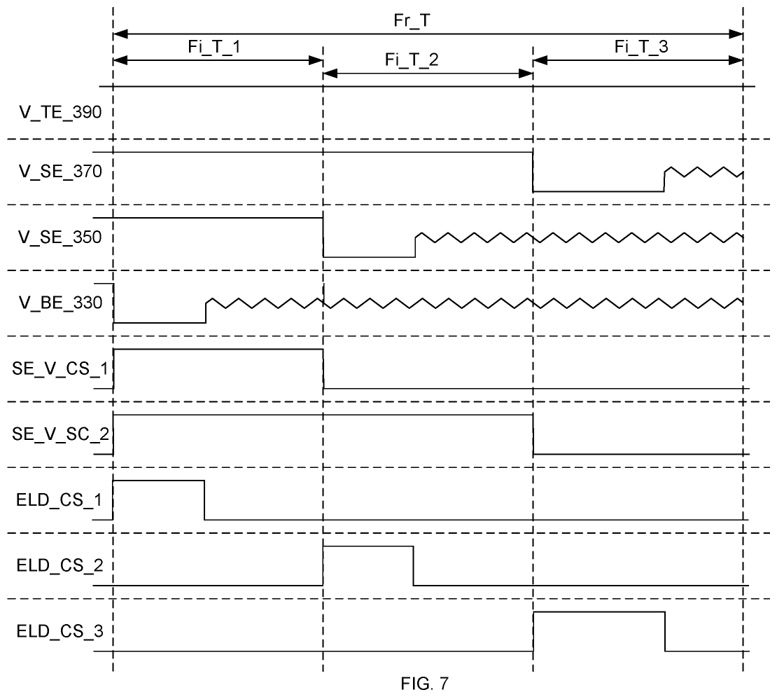

FIG. 7 shows a timing diagram that can be used with pixel 300 in accordance with one embodiment of the present invention. Specifically FIG. 7 shows one frame time period Fr_T, in which one frame of a video is shown on the display. Frame time period Fr_T is divided into a three field time periods Fi_T_1, Fi_T_2, and Fi_T_3. As explained above, some embodiments of the present invention use pixel 300 with a field sequential color system. Thus, only one color is displayed in each field time period. In FIG. 7, electroluminescent device 340 is used in field time periods Fi_T_1, electroluminescent device 360 is used in field time periods Fi_T_2, and electroluminescent device 380 is used in field time periods Fi_T_3.

Like FIG. 5, FIG. 7 shows the voltage on top electrode 390, which is labeled V_TE_390, the voltage on shared electrode 370, which is labeled V_SE_370, the voltage on shared electrode 350, which is labeled V_SE_350, and the voltage on bottom electrode 330, which is labeled V_BE_330. In addition, FIG. 7 shows electroluminescent device control signals ELD_CS_1, ELD_CS_2, and ELD_CS_3, which control voltage controlled current sources 630, 650, and 670, respectively. Furthermore, FIG. 7 also shows shared electrode voltage control signals SE_V_CS_1 and SE_V_CS_2, which control controlled pull up circuits 655 and 675, respectively.

As explained above, electroluminescent device control signals ELD_CS_1 controls electroluminescent device 340, which is only active during field time period Fi_T_1. Therefore, during field time periods Fi_T_2 and Fi_T_3, electroluminescent device control signals ELD_CS_1 is at logic low. During field time period Fi_T_1, electroluminescent device control signals ELD_CS_1 is at logic high to turn on electroluminescent device 340 and at logic low to turn off electroluminescent device 340. Thus in FIG. 7, electroluminescent device control signals ELD_CS_1 is shown to transition to logic high at the beginning of field time period Fi_T_1 and transition to logic low during field time period Fi_T_1 and remain at logic low throughout Field time periods Fi_T_2 and Fi_T_3.

Electroluminescent device control signals ELD_CS_2 controls electroluminescent device 360, which is only active during field time period Fi_T_2. Therefore, during field time periods Fi_T_1 and Fi_T_3, electroluminescent device control signals ELD_CS_2 is at logic low. During field time period Fi_T_2, electroluminescent device control signals ELD_CS_2 is at logic high to turn on electroluminescent device 360 and at logic low to turn off electroluminescent device 360. Thus in FIG. 7, electroluminescent device control signals ELD_CS_2 is shown to transition to logic high at the beginning of field time period Fi_T_2 and transition to logic low during field time period Fi_T_2 and remain at logic low throughout Field time periods Fi_T_1 and Fi_T_3.

Electroluminescent device control signals ELD_CS_3 controls electroluminescent device 380, which is only active during field time period Fi_T_3. Therefore, during field time periods Fi_T_1 and Fi_T_2, electroluminescent device control signals ELD_CS_3 is at logic low. During field time period Fi_T_3, electroluminescent device control signals ELD_CS_3 is at logic high to turn on electroluminescent device 380 and at logic low to turn off electroluminescent device 380. Thus in FIG. 7, electroluminescent device control signals ELD_CS_3 is shown to transition to logic high at the beginning of field time period Fi_T_3 and transition to logic low during field time period Fi_T_3 and remain at logic low throughout Field time periods Fi_T_1 and Fi_T_2.

Shared electrode voltage control signal SE_V_CS_1 controls controlled pull up circuit 655. During field time Fi_T_1, shared electrode voltage control signal SE_V_CS_1 is at logic high which activates controlled pull up circuit 655 to pull the voltage V_SE_350 on shared electrode 350 to a high voltage. During field times Fi_T_2 and FI_T_3, shared electrode voltage control signal SE_V_CS_1 is at logic low to deactivate controlled pull up circuit 655. When deactivated controlled pull up circuit 655 does not control the voltage on shared electrode 350. Thus voltage V_SE_350 on shared electrode 350 would either float or be controlled by voltage controlled current source 650.

Shared electrode voltage control signal SE_V_CS_2 controls controlled pull up circuit 675. During field times Fi_T_1 and Fi_T_2, shared electrode voltage control signal SE_V_CS_2 is at logic high which activates controlled pull up circuit 675 to pull the voltage V_SE_370 on shared electrode 370 to a high voltage. During field time FI_T_3, shared electrode voltage control signal SE_V_CS_2 is at logic low to deactivate controlled pull up circuit 675. When deactivated controlled pull up circuit 675 does not control the voltage on shared electrode 370. Thus voltage V_SE_370 on shared electrode 370 would either float or be controlled by voltage controlled current source 670.

Because top electrode 390 is coupled to supply voltage Vdd, voltage V_TE_390 remains high during the entirety of frame time period Fr_T. As explained above, controlled pull up circuit 675 pulls shared electrode 370 to supply voltage Vdd when electroluminescent device 340 or electroluminescent device 360 can be activated. Therefore, voltage V_SE_370 on shared electrode 370 is high during field time period Fi_T_1 and field time period Fi_T_2. During field time Fi_T_2, voltage V_SE_370 on electrode 370 is controlled by electroluminescent device control signal CLD_CS_3 through voltage controlled current source 670. When electroluminescent device control signal ELD_CS_3 is at logic high, voltage V_SE_370 on shared electrode 370 is pulled to a low voltage and when electroluminescent device control signal ELD_CS_3 is at logic low, voltage V_SE_370 is floating, which is represented by a diagonal line segments in between high and low. While voltage V_SE_370 is floating, shared electrode 370 is not driven and is in a high impedance state.

As explained above, controlled pull up circuit 655 pulls shared electrode 350 to supply voltage Vdd when electroluminescent device 340 can be activated. Therefore, voltage V_SE_350 on shared electrode 350 is pulled to supply voltage Vdd during field time period Fi_T_1. During field time periods Fi_T_2 and Fi_T_3, voltage V_SE_350 on shared electrode 350 is controlled by electroluminescent device control signal ELD_CS_2 through voltage controlled current source 650. When electroluminescent device control signal ELD_CS_2 is at logic high, voltage V_SE_350 on shared electrode 350 is pulled to a low voltage and when electroluminescent device control signal ELD_CS_2 is at logic low, voltage V_SE_350 is floating. While voltage V_SE_350 is floating, shared electrode 350 is not driven and is in a high impedance state.

During field time periods Fi_T_1, Fi_T_2 and Fi_T_3, voltage V_BE_330 on bottom electrode 330 is controlled by electroluminescent device control signal ELD_CS_1 through voltage controlled current source 630. When electroluminescent device control signal ELD_CS_1 is at logic high, voltage V_BE_330 on bottom electrode 330 is pulled to a low voltage and when electroluminescent device control signal ELD_CS_1 is at logic low, voltage V_BE_330 is floating. While voltage V_BE_330 is floating, bottom electrode 330 is not driven and is in a high impedance state.

An electroluminescent device is active (i.e. emits light) when a voltage difference on the top and bottom of the electroluminescent device causes sufficient current to run through the electroluminescent device. During field time period Fi_T_1, voltage V_TE_390 on top electrode 390, voltage V_SE_370 on shared electrode 370, and voltage V_SE_350 are at supply voltage Vdd. Thus, no current flows through electroluminescent device 380 (which is between top electrode 390 and shared electrode 370). Similarly no current flows through electroluminescent device 360 (which is between shared electrode 370 and shared electrode 350). Voltage V_BE_330 on bottom electrode is driven to a low voltage for part of field time period Fi_T_1 and floating during the rest of field time period Fi_T_1. When voltage V_BE_330 is at low voltage electroluminescent device 340 activates because a current flows from shared electrode 350 (at high voltage) to bottom electrode 330 (at low voltage). But when voltage V_BE_330 is floating no current flows and electroluminescent device 340 is deactivated.

During field time period Fi_T_2, voltage V_TE_390 on top electrode 390 and voltage V_SE_370 on shared electrode 370 are at supply voltage Vdd. Thus, no current flows through electroluminescent device 380 (which is between top electrode 390 and shared electrode 370). Voltage V_SE_350 on shared electrode 350 is driven to a low voltage for part of field time period Fi_T_2 and floating during the rest of field time period Fi_T_2. When voltage V_SE_350 is at low voltage electroluminescent device 360 activates because a current flows from shared electrode 370 (at high voltage) to shared electrode 350 (at ground voltage). But when voltage V_SE_350 is floating no current flows and electroluminescent device 360 is deactivated. During field time period Fi_T_2, voltage V_BE_330 on bottom electrode 330 is floating therefore no current flows through electroluminescent device 340, which remains deactivated during field time period Fi_T_2.

During field time period Fi_T_3, voltage V_TE_390 on top electrode 390 is at supply voltage Vdd. Voltage V_SE_370 on shared electrode 370 is driven to a low voltage for part of field time period Fi_T_3 and floating during the rest of field time period Fi_T_3. When voltage V_SE_370 is at low voltage electroluminescent device 380 activates because a current flows from top electrode 390 (at high voltage) to shared electrode 370 (at low voltage). But when voltage V_SE_370 is floating no current flows and electroluminescent device 380 is deactivated. During field time period Fi_T_3, voltage V_BE_330 on bottom electrode 330 and voltage V_SE_350 on shared electrode 350 are floating therefore no current flows through electroluminescent device 340 and electroluminescent device 360, which remain deactivated during field time period Fi_T_3. Thus pixel 300 operating in the manner illustrated by FIG. 6 and FIG. 7 can be used to display full color using a field sequential color system.

In the various embodiments of the present invention, novel structures and methods have been described for creating a pixel having shared electrodes. The various embodiments of the structures and methods of this invention that are described above are illustrative only of the principles of this invention and are not intended to limit the scope of the invention to the particular embodiment described. For example, in view of this disclosure those skilled in the art can define other electroluminescent devices, conductors, shared conductors, carrier transport layers, electroluminescent layers, quantum dot layers, LEDs, OLEDS, current sources, pull up circuits, pull down circuits, frame time periods, sub-periods, and so forth, and use these alternative features to create a method or system according to the principles of this invention. Thus, the invention is limited only by the following claims.

1. A pixel comprising:
a bottom electrode;
a first electroluminescent device coupled to the bottom electrode;
a first shared electrode coupled to the first electroluminescent device; wherein the first shared electrode and the bottom electrode can be used to operate the first electroluminescent device;
a second electroluminescent device coupled to the first shared electrode;
a second shared electrode coupled to the second electroluminescent device; wherein the first shared electrode and the second shared electrode can be used to operate the second electroluminescent device;
a third electroluminescent device coupled to the second shared electrode;
a top electrode, wherein the top electrode and the second shared electrode can be used to operate the third electroluminescent device;
wherein the first electroluminescent device is activated, the second electroluminescent device is deactivated, and the third electroluminescent device is deactivated during a first field time period by
driving the bottom electrode to a high voltage; and
driving the first shared electrode to a low voltage;
driving the second shared electrode to the low voltage; and
driving the top electrode to the low voltage.

2. The pixel of claim 1, wherein:
the first electroluminescent device is stacked on top of the bottom electrode; and
the first shared electrode is stacked on top of the first electroluminescent device.

3. The pixel of claim 2, wherein:
the second electroluminescent device is stacked on top of the first shared electrode; and
the second shared electrode is stacked on top of the second electroluminescent device.

4. The pixel of claim 3, wherein:
the third electroluminescent device is stacked on top of the second shared electrode; and
the top electrode is stacked on top of the third electroluminescent device.

5. (canceled)

6. (canceled)

7. The pixel of claim 1, wherein the first electroluminescent device is deactivated, the second electroluminescent device is activated, and the third electroluminescent device is deactivated during a second field time period by:
driving the top electrode to the low voltage;
setting the bottom electrode to a high impedance state;
driving the first shared electrode to the high voltage; and
driving the second shared electrode to the low voltage.

8. (canceled)

9. The pixel of claim 1, wherein the first electroluminescent device is deactivated, the second electroluminescent device is deactivated, and the third electroluminescent device is activated during a third field time period by:
setting the bottom electrode to the high impedance state;
setting the first shared electrode to the high impedance state; and
driving the second shared electrode to the high voltage; and
driving the top electrode to the low voltage.

10. A pixel comprising:
a bottom electrode;
a first electroluminescent device coupled to the bottom electrode;
a first shared electrode coupled to the first electroluminescent device; wherein the first shared electrode and the bottom electrode can be used to operate the first electroluminescent device;
a second electroluminescent device coupled to the first shared electrode;
a second shared electrode coupled to the second Edward Mao electrode and the second shared electrode can be used to operate the second electroluminescent device;
a third electroluminescent device coupled to the second shared electrode;
a top electrode, wherein the top electrode and the second shared electrode can be used to operate the third electroluminescent device;
wherein the first electroluminescent device is activated, the second electroluminescent device is deactivated, and the third electroluminescent device is deactivated during a first field time period by:
driving the bottom electrode to a low voltage;
driving the first shared electrode to a high voltage;
driving the second shared electrode to the high voltage; and
driving the top electrode to the high voltage.

11. (canceled)

12. The pixel of claim 10 wherein the first electroluminescent device is deactivated, the second electroluminescent device is activated, and the third electroluminescent device is deactivated by:
setting the bottom electrode to a high impedance state;
driving the first shared electrode to the low voltage;
driving the second shared electrode to the high voltage; and
driving the top electrode to the high voltage.

13. (canceled)

14. The pixel of claim 1, wherein the first electroluminescent device is deactivated, the second electroluminescent device is deactivated, and the third electroluminescent device is activated during a second field time period by:
setting the bottom electrode to the high impedance state;
setting the first shared electrode to the high impedance state; and
driving the second shared electrode to the low voltage; and
driving the top electrode to the high voltage.

15. The pixel of claim 1 further comprising:
a first current source coupled to the bottom electrode;
a second current source coupled to the first shared electrode; and
a third current source coupled to the second shared electrode.

16. The pixel of claim 15 further comprising:
a first controlled pull down circuit coupled to the first shared electrode; and
a second controlled pull down circuit coupled to the second shared electrode.

17. The pixel of claim 15 further comprising:
a first controlled pull up circuit coupled to the first shared electrode; and
a second controlled pull up circuit coupled to the second shared electrode.

18. The pixel of claim 1, wherein the first electroluminescent device further comprises:
a first-type transport layer;
an electroluminescent layer on top of the first-type transport layer; and
a second-type transport layer on top of the electroluminescent layer.

19. The pixel of claim 18, wherein:
the first-type transport layer is a hole transport layer; and
the second-type transport layer is an electron transport layer.

20. The pixel of claim 18, wherein:
the first-type transport layer is an electron transport layer; and
the second-type transport layer is a hole transport layer.

21. The pixel of claim 18, wherein the electroluminescent layer includes a plurality of quantum dots.

22. The pixel of claim 18, wherein the electroluminescent layer comprises organic light emitting material.

23. The pixel of claim 18, wherein the first-type transport layer of the first electroluminescent device is on top of the bottom electrode.

24. The pixel of claim 23, wherein the first shared electrode is on top of the second-type transport layer of the first electroluminescent device.

25. The pixel of claim 1, wherein the first electroluminescent device is a quantum dot device.

26. The pixel of claim 1, wherein the first electroluminescent device is an organic light emitting diode.

27. The pixel of claim 1, wherein the first electroluminescent device is a light emitting diode.

28. The pixel of claim 1 wherein:
the first electroluminescent device produces a first color light;
the second electroluminescent device produces a second color light; and
the third luminescent device produces a third color light.

29. The pixel of claim 28, wherein:
the first color light is red;
the second color light is green; and
the third color light is blue.
